(19) United States
(12) Patent Application Publication
(10) Pub. No.: US 2008/0136423 A1
(43) Pub. Date: Jun. 12, 2008

(54) Measurement Arrangement for Determining the Characteristic line Parameters by Measuring Scattering Parameters

(76) Inventors: Thomas Ludwig, Sindelfingen (DE); Helmut Schettler, Dettenhausen (DE); Thomas-Michael Winkel, Schonaich (DE)

Correspondence Address: INTERNATIONAL BUSINESS MACHINES CORPORATION, IPLAW DEPARTMENT, 2455 SOUTH ROAD - MS P386, POUGHKEEPSIE, NY, 12601, US

(21) Appl. No.: 11/567,339

(22) Filed: Dec. 6, 2006

(51) Int. Cl. G01R 27/00

(52) U.S. Cl. 324/650

(57) ABSTRACT

The present invention relates to a measurement arrangement for determining the characteristic line parameters by measuring the S-parameters as a function of the frequency of an electrical signal line that achieves an increased measurement bandwidth, namely a measurement bandwidth >4 GHz. To achieve this the electrical signal line under test has several neighboring signal lines which are connected to ground on one side and left open on the opposite side in an alternating manner.

The present invention relates to a measurement arrangement for determining the characteristic line parameters by measuring scattering parameters (S-parameters) as a function of the frequency of an electrical signal line according to the features of claim 1.

### BACKGROUND OF THE INVENTION

Model to hardware correlation measurements on all packaging levels are essential in today's development process of high performance computers. Different measurement techniques in time and frequency domain require different measurement set-ups and test site designs. One demand for the test site is to be equivalent to the product. Therefore, transmission lines on a chip need to be measured in the product line power and ground wiring distributed in all metal layers on chip. In addition it is not only of interest to measure a single transmission line but also with a product like wiring channel utilization. This is essential to image the real signal coupling behavior on the chip and the shielding effect of metal layers between top metal layers and the semi conducting substrate.

A known measurement technique is the so-called S-parameter measurements, see Zinke/Brunswig, “Lehrbuch der Hockfrequenztechnik”, Springer-Verlag, 1989. S-parameters are reflection and transmission coefficients of an n-port network. The equivalent for a single transmission line e.g. is a two port network characterized by a 2×2 S-parameter matrix.

A two-port network is described by the relationship

$$( \begin{matrix}{b}_{1} \\ {b}_{2}\end{matrix} ) = ( \begin{matrix}{S}_{11} & {S}_{12} \\ {S}_{21} & {S}_{22}\end{matrix} ) \cdot ( \begin{matrix}{a}_{1} \\ {a}_{2}\end{matrix} )$$

wherein S₁₁, S₂₂, S₁₂ and S₂₁ are the S-parameters, namely

S₁₁=Input reflection coefficient with the output port terminated by a matched load,

S₁₂=Output reflection coefficient with the input terminated by a matched load,

S₁₂=Reverse transmission (insertion) gain with the input port terminated in a matched load,

S₂₁=Forward transmission (insertion) gain with the output port terminated in a matched load, and

the variables a₁, a₂ and B₁, b₂ are complex voltage waves incident on and reflected from the first and second port of the two-port network.

In the present case the S-parameter measurements are an advantageous measurement technique because the S-parameter are easier to measure and work with at high frequencies than other kinds of parameters.

Furthermore different methods are well-known in the state of the art to extract other characteristic frequency dependent line parameters, such as characteristic impedance z(f) or propagation constant ν(f) etc., from the S-parameter measurements, so that these parameters can easily be obtained from the S-parameter measurements. Thomas-Michael Winkel, Lohit Sagar Dutts, Hartmut Grabinski, “An Accurate Determination of the Characteristic Impedance of Lossy Lines on Chips Based on High Frequency S-Parameter Measurements”, IEEE Multi-Chip Module Conference MCWC'96, pp. 190-195, February 1996, Thomas-Michael Winkel, “Untersuchung der Kopplung zwischen Leitungen auf Silizium-Substraten unterschiedlicher Leitfähigkeit unter Verwendung breibandiger Messungen”, Ph D. Thesis, University of Hannover, November 1997.

A special requirement for the high frequency S-parameter measurements in this case is that the transmission lines are not connected to any active device on chip. Due to this, parallel signal lines would be floating if not connected to any driver and receiver. A problem occurs when parallel lines on the test site have to be connected to some point in absence of drivers, receivers and transistors.

One option is to leave both sides of the signal lines open, but floating lines do not correspond to the product and will therefore alter the measurement results.

A second option is to connect both ends of the parallel signal lines to ground. In this case all signal lines act as ground lines which is also not corresponding to the product.

In principle a driver has a low impedance while a receiver has a high impedance. Therefore a third option is to connect one side of the parallel signal line and leave the opposite side open. This option imitates the product but the problem that occurs here is that high frequency measurements are band limited to less than 4 GHz because in the higher frequency range both measurements ports present a different electrical behavior on both ports. While one port just sees open parallel lines the opposite port just sees grounded parallel lines. As a result, for frequencies >4 GHz not only one signal line mode will be excited in the test structure.

As evidenced from the forgoing discussion, it is desirable to provide a measurement system for determining the S-parameters as a function of the frequency of an electrical signal line which does not suffer from the above-note drawbacks and leads to a significant gain of the measurement bandwidth.

### SUMMARY OF THE INVENTION

The present invention relates to a measurement arrangement for determining the characteristic transmission line parameters by measuring the S-parameters as a function of the frequency of an electrical signal line that achieves an increased measurement bandwidth, namely a measurement bandwidth >4 GHz.

The measurement arrangement according to the invention is characterized by what is specified in the independent claim 1.

Advantageous embodiments of the invention are specified in the dependent claims.

the inventive measurement arrangement comprises a signal line under test—measuring line—and several neighboring signal lines, wherein the measuring line as well as the neighboring signal lines having a first and a second end, representing port 1 (S₁₁) and port 2 (S₂₂) of a two-port network. According to the invention one end of each neighboring signal line is terminated by a low impedance and the other end of each neighboring signal line is terminated by a high impedance, so that the first and second ends of all neighboring signal lines are terminated by a low impedance and a high impedance, respectively, and the number of neighboring signal lines having a low impedance on their first ends or their second ends is equal or nearly equal to the number of neighboring signal lines having a high impedance on their first or second ends.

As a result of the special connection pattern both ports look at least nearly identical. Therefore, only one signal mode is excited and the frequency bandwidth is increased significantly.

In accordance with a feature of the invention, the low impedance is formed by a closed-ended line (connection to ground) and the high impedance is formed by an open-ended line.

In accordance with still another feature of the invention, the measuring line is in a plane arrangement and the neighboring signal lines are arranged in-plane to the measuring line in a line pattern matter or in a parallel arrangement.

Preferably, neighboring signal lines arranged directly adjacent to each other have a different impedance on their first ends and their second ends, so that the first ends and second ends of all neighboring signal lines are alternatingly terminated by a low impedance and a high impedance, respectively. This leads to an alternating arrangement on port 1 and port 2, respectively. This means both ports have an identical appearance and as a result the frequency bandwidth is increased to more than 20 GHz.

According to another feature of the invention, the number of neighboring signal lines on both sides of the measuring line is equal.

Further, the neighboring signal lines arranged directly adjacent to the measuring line may have a different or identical impedance on their first ends and their second ends, respectively.

In accordance with still another feature of the invention, the measuring line and the neighboring signal lines are signal lines in a multi-layer chip, wherein the direction of the signal lines between two adjacent layers is rotated by 90°, and the measuring line and its neighboring signal lines are arranged in the same layer—measuring layer—in a parallel arrangement, and the signal lines in the layers adjacent to the measuring layer—neighboring layer lines—are also arranged in a parallel arrangement and having a different impedance on their first ends and their second ends, respectively, so that the first ends and second ends of all neighboring layer lines are terminated by a low impedance and a high impedance, respectively, and the number of neighboring layer lines having a low impedance on their first ends or their second ends is equal or nearly equal to the number of neighboring layer lines having a high impedance on their first ends or their second ends.

Preferably, neighboring layer lines arranged directly adjacent to each other have a different impedance on their first ends and their second ends, so that the first ends and second ends of all neighboring layer lines are alternatingly terminated by a low impedance and a high impedance, respectively. This alternating arrangement of the neighboring layer lines in connection with the alternating arrangement of neighboring signal lines lead to a significant gain of measurement bandwidth. Experiments have shown that due to the inventive arrangement of on chip wiring the bandwidth is increased up to 20 GHz.

According to another feature of the invention the measuring line and the neighboring lines are arranged as a bunch.

In order to achieve a nearly identical appearance of both ports of the bunch the ends of the neighboring signal lines with a low impedance and a high impedance, respectively, are arranged in an equal or nearly equal manner regarding an imaginary cross-sectional area of the bunch.

### BRIEF DESCRIPTION OF THE DRAWINGS

Additional objects, advantages, and features of the present invention will become apparent from the following description taken in conjunction with the accompanying drawings.

FIG. 1 Schematic view of a multi-layer chip having a connection pattern of the signal lines according to the state of the art,

FIG. 2 Magnitude of measured reflection parameters S₁₁ and S₂₂ on port 1 and port 2 according to FIG. 1,

FIG. 3 Phase of measured reflection parameters S₁₁ and S₂₂ on port 1 and port 2 according to FIG. 2,

FIG. 4 Schematic view of a multi-layer chip having a connection pattern of the signal lines according to the invention,

FIG. 5 Magnitude of measured reflection parameters S₁₁ and S₂₂ for a port symmetrical test site according to FIG. 4, and

FIG. 6 Phase of measured reflection parameters S₁₁ and S₂₂ for a port symmetrical test site according to FIG. 4.

### DETAILED DESCRIPTION OF THE PRESENT INVENTION

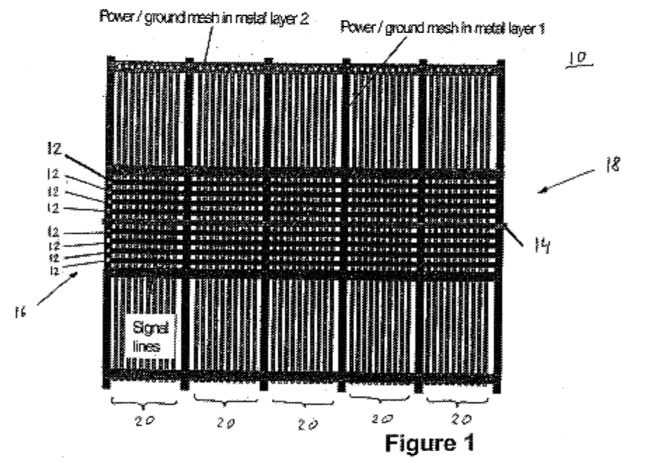

FIG. 1 shows a schematic view of a multi-layer chip 10 having an unsymmetrical connection pattern of the signal lines (State of the art).

In order to image the real signal coupling behavior on the chip 10 additional signal lines 12, the so-called neighboring signal lines, were added adjacent to a signal line under test 14, the so-called measuring line, in the same layer.

The neighboring signal lines 12 were connected by vias to ground on one side 16, here port 1, to imitate a driver and left open on the opposite side 18, here port 2, to imitate a receiver.

In order to image the shielding effect of metal layers between top metal layers and the semi conducting substrate additional signal lines 20, the so-called neighboring layer lines, were added in the bottom metal layers. All neighboring signal lines 20 were also connected to ground on one side and left open on the opposite side.

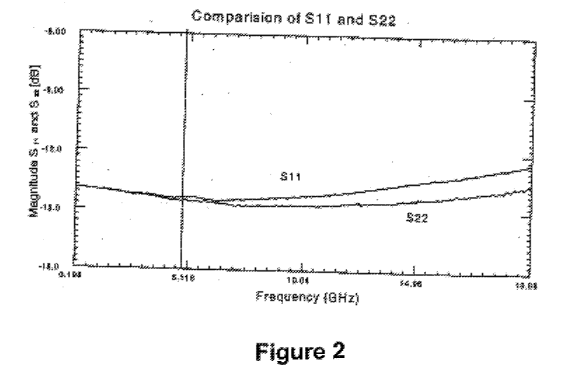

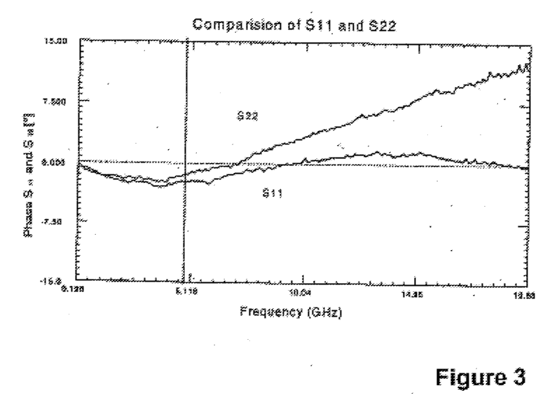

As a result the measured reflection parameters S₁₁ and S₂₂ as depicted in FIGS. 2 and 3 are no more identical for higher frequencies.

Due to random and systematically measurement errors the measurement uncertainty for the magnitude is usually ˜3%. For frequencies >4 GHz the difference between both reflection parameters exceeds this value for the magnitude as well as for the phase. This means more than just one signal line mode is excited in this test structures. Therefore, all extracted transmission line parameters are just valid up to 4 GHz.

In order to increase the frequency bandwidth of the extracted data, the test site design needs to be modified according to the invention. To ensure that the measured reflection parameters for port 1 (S₁₁) 16 and port 2 (S₂₂) 18 are nearly equal. This goal can be achieved by making both ports 16, 18 symmetrical from an electrical point of view.

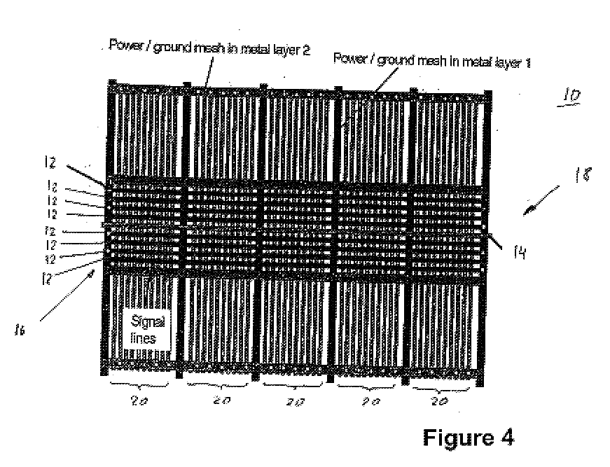

As shown in FIG. 4 the port symmetry was achieved by connection each second of the adjacent neighboring signal lines 12 to ground on port 1 (S₁₁) 16 while all the other adjacent neighboring signal lines 12 are left open on port 1 (S₁₁) 16. On port 2 (S₂₂) 18 the adjacent neighboring signal lines 12 which are left open on port 1 (S₁₁) 16 are grounded on port 2 (S₂₂) 18. All other neighboring layer lines 20 in other metal layers are also connected to ground in the same alternating manner.

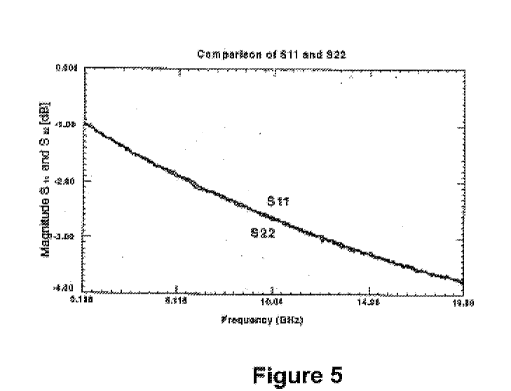

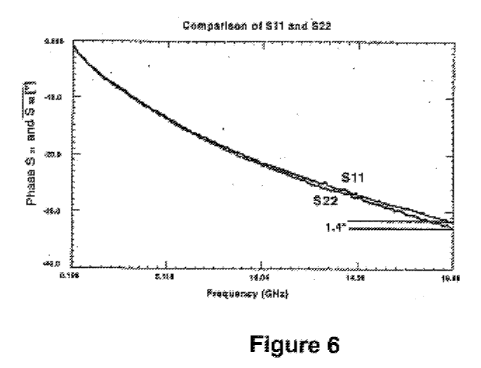

As a result of this change, the measured reflection parameters for port 1 (S₁₁) 16 and port 2 (S₂₂) 18 are nearly identical as depicted in FIG. 5 for the magnitudes and FIG. 6 for the phases in the frequency range at least up to 20 GHz. Some differences between both measured reflection parameters are usual but as a criterion for good measurement, the differences should not exceed the expected measurement uncertainty of 0.03 db (at 20 GHz) for the magnitude and 2° (at 20 GHz) for the phase.

### LIST OF REFERENCE SIGNS

10 multi-layer chip

12 neighboring signal lines

14 measuring line

16 port 1

18 port 2

20 neighboring layer lines

1. Measurement arrangement for determining the characteristic line parameters by measuring scattering parameters (S-parameters) as a function of the frequency of an electrical signal line—measuring line—, with the measuring line having several neighboring signal lines and the measuring line as well as the neighboring signal lines having a first end and a second end, respectively, characterized in that one end of each neighboring signal line is terminated by a low impedance and the other end of each neighboring signal line is terminated by a high impedance, so that the first and second ends of all neighboring signal lines are terminated by a low impedance and a high impedance, respectively, and that the number of neighboring signal lines having a low impedance on their first ends or their second ends is equal or nearly equal to the number of neighboring signal lines having a high impedance on their first ends or their second ends.

2. Measurement arrangement according to claim 1, characterized in that the low impedance is formed by a closed-end line (connection to ground) and the high impedance is formed by an open-ended line.

3. Measurement arrangement according to claim 1, characterized in that the measuring line is in a plane arrangement and the neighboring signal lines are arrangement in-plane to the measuring line in a line pattern matter.

4. Measurement arrangement according to claim 1, characterized in that the measuring line is in a plane arrangement and the neighboring signal lines are arranged in-plane to the measuring line in a parallel arrangement.

5. Measurement arrangement according to claim 1, characterized in that neighboring signal lines arranged directly adjacent to each other have a different impedance on their first ends and second their ends, respectively.

6. Measurement arrangement according to claim 1, characterized in that the number of neighboring signal lines on both sides of the measuring line is equal.

7. Measurement arrangement according to claim 1, characterized in that the neighboring signal lines arranged directly adjacent to the measuring line have a different impedance on their first ends and their second ends, respectively.

8. Measurement arrangement according to claim 1, characterized in that the neighboring signal lines arranged directly adjacent to the measuring line have an identical impedance on their first ends and their second ends respectively.

9. Measurement arrangement according to claim 1, characterized in that the measuring line end and the neighboring signal lines are signal lines in a multi-layer chip, wherein the direction of the signal lines between two adjacent layers is rotated by 90°, that the measuring line and its neighboring signal lines are arranged in the same layer—measuring layer—in a parallel arrangement and that the signal lines in the layers adjacent to the measuring layer —neighboring layer lines—are arranged in a parallel arrangement having a different impedance on their first ends and their second ends, respectively, so that the first and second ends of all neighboring layer lines are terminated by a low impedance and a high impedance, respectively, and that the number of neighboring layer lines having a low impedance on their first ends or their second ends is equal or nearly equal to the number of neighboring layer lines having a high impedance on their first ends or their second ends.

10. Measurement arrangement according to claim 9, characterized in that neighboring layer lines arranged directly adjacent to each other have a different impedance on their first ends and their second ends, respectively.

11. Measurement arrangement according to claim 1, characterized in that the measuring line and the neighboring signal lines are arranged as a bunch.

12. Measurement arrangement according to claim 11, characterized in that in an imaginary cross-sectional area of the bunch the ends of the neighboring signal lines with a low impedance and a high impedance, respectively, are arranged in an equal or nearly equal manner.
